(19) United States
(12) Patent Application Publication
(10) Pub. No.: US 2004/0188852 A1
(43) Pub. Date: Sep. 30, 2004

(54) SEMICONDUCTOR DEVICE

(75) Inventors: Kazuhiro Umemoto, Kusatsu-shi (JP); Satsuo Kiyono, Moriyama-shi (JP)

Correspondence Address: IBM MICROELECTRONICS, INTELLECTUAL PROPERTY LAW, 1000 RIVER STREET, 972 E, ESSEX JUNCTION, VT, 05452, US

(73) Assignee: INTERNATIONAL BUSINESS MACHINES CORPORATION, Armonk, NY (US)

(21) Appl. No.: 10/708,809

(22) Filed: Mar. 26, 2004

(30) Foreign Application Priority Data
Mar. 27, 2003 (JP) 2003-087826

(51) Int. Cl. H01L 23/48

(52) U.S. Cl. 257/777

(57) ABSTRACT

A semiconductor device having two or more semiconductor chips stacked upon one another in a manner that makes them less susceptible to damage from warping of the semiconductor device.

### BACKGROUND OF INVENTION

1. Field of the Present Invention

The present invention relates to a semiconductor device and, more specifically, relates to a DCS (Dual Chip Stack) semiconductor device.

2. Description of Related Art

Semiconductor devices are often employed in FPGA (Fine Pitch ball Grid Array) systems and so forth. FIG. 7 (Prior Art) is a sectional view showing a structure of a conventional DCS semiconductor device.

Referring to FIG. 7, the DCS semiconductor device 1 comprises a substrate 11, a bottom semiconductor chip 12 including an electrical circuit (not shown) such as an SRAM (Static Random Access Memory), and a top semiconductor chip 13 including an electrical circuit (not shown) such as a flash memory. The bottom semiconductor chip 12 is mounted on the substrate 11 using adhesive paste 14. The top semiconductor chip 13 is mounted on the bottom semiconductor chip 12 using adhesive paste 15. Further, resin 16 is molded on the substrate 11 so as to cover the bottom semiconductor chip 12 and the top semiconductor chip 13.

In the conventional DCS semiconductor device 1, inasmuch as the sizes of the bottom semiconductor chip 12 and the top semiconductor chip 13 are equal to each other, even if these chips are subjected to thermal expansion in the molding process of the resin 16, stresses to be generated therein will be equal to each other. Therefore, the thermal expansion of the semiconductor chips 12 and 13 does not cause warping of the DCS semiconductor device 1. On the other hand, since the thermal expansion coefficient of the resin 16 differs from that of the semiconductor chips 12 and 13, and the resin 16 may also be contracted, this may cause warping of the DCS semiconductor device 1 as shown in FIG. 8 (Prior Art). However, even if it is warped, the warping amounts of the bottom semiconductor chip 12 and the top semiconductor chip 13 are substantially the same. Therefore, it is unlikely that stresses are generated concentratedly in the DCS semiconductor device 1.

As described above, the size of the top semiconductor chip 13 is the same as that of the bottom semiconductor chip 12 in the conventional DCS semiconductor device 1. However, as shown in FIG. 9, it is hereby assumed that a DCS semiconductor device 2 employs, instead of the top semiconductor chip 13, a top semiconductor chip 21 having a size smaller than that of the bottom semiconductor chip 12. As appreciated, this DCS semiconductor device 2 is only for explaining a theme of the present invention, and does not constitute the prior art.

In the DCS semiconductor device 2, resin 16 is filled in the portion where the top semiconductor chip 13 is provided in the conventional DCS semiconductor device 1. Inasmuch as the thermal expansion coefficient of the resin 16 largely differs from that of the semiconductor chips 12 and 21, the DCS semiconductor device 2 tends to be warped as shown in FIG. 10. Moreover, inasmuch as the size of the top semiconductor chip 21 is smaller than that of the bottom semiconductor chip 12, warping of the bottom semiconductor chip 12 becomes greater than that of the top semiconductor chip 21. Therefore, stresses are concentrated in the neighborhood of portions where edges 211 of a lower surface of the top semiconductor chip 21 contact an upper surface of the bottom semiconductor chip 12 and in the neighborhood of portions where edges 121 of a lower surface of the bottom semiconductor chip 12 contact an upper surface of a substrate 11. As a result, there is a possibility that the upper surfaces of the bottom semiconductor chip 12 and the substrate 11 may be damaged. This problem becomes more significant as the position of the top semiconductor chip 21 approaches an end of the bottom semiconductor chip 12 as compared with being located at the center thereof. This is because stresses are generated asymmetrically.

As one method of solving such a problem, it is considered that adhesive pastes 14 and 15 may be applied thicker. However, there is a possibility that a steam explosion phenomenon may occur in the adhesive pastes 14 and 15 upon reflow-soldering the DCS semiconductor device 2 to a printed circuit board or the like.

It would, therefore, be a distinct advantage to have a semiconductor device that can suppress damage to an internal semiconductor chip caused by a stress produced by warping of the semiconductor device. The present invention provides such a semiconductor device.

### SUMMARY OF INVENTION

In one aspect, the present invention is a semiconductor device includes a substrate, a first semiconductor chip, and a second semiconductor chip. The first semiconductor chip is mounted on the substrate. The second semiconductor chip is mounted on the first semiconductor chip, and is smaller in size and thickness than the first semiconductor chip.

The second semiconductor chip being smaller in size than the first semiconductor chip, but the first semiconductor chip is thicker than the second semiconductor chip. Accordingly, even if the semiconductor device is warped, stresses are reluctant to occur concentratedly. Therefore, damage to the first semiconductor chip caused by the second semiconductor chip can be suppressed.

In yet another aspect, the present invention is a r semiconductor device having a substrate, a first semiconductor chip, and a second semiconductor chip. The first semiconductor chip is mounted on the substrate. The second semiconductor chip is mounted on the first semiconductor chip, and is smaller in size than the first semiconductor chip. An edge of a lower surface of the second semiconductor chip confronting an upper surface of the first semiconductor chip is chamfered.

The second semiconductor chip is smaller in size than the first semiconductor chip, but the edge of the lower surface of the second semiconductor chip is chamfered. Accordingly, even if the semiconductor device is warped, stresses are reluctant to occur concentratedly. Therefore, damage to the first semiconductor chip caused by the second semiconductor chip can be suppressed.

### BRIEF DESCRIPTION OF DRAWINGS

FIG. 1 is a plan view showing an external appearance of a DCS semiconductor device according to a first preferred embodiment of the present invention.

FIG. 2 is a sectional view of the DCS semiconductor device, taken along line I-II in FIG. 1.

FIG. 3 is a graph showing variation of distortion when the size and thickness of a bottom semiconductor chip are changed while keeping constant the size and thickness of a top semiconductor chip in the DCS semiconductor device shown in FIG. 1.

FIG. 4 is a graph wherein the size and thickness of the bottom semiconductor chip shown in FIG. 3 are converted into the ratios thereof relative to the size and thickness of the top semiconductor chip.

FIG. 5 is a sectional view showing a structure of a DCS semiconductor device according to a second preferred embodiment of the present invention.

FIG. 6 is a sectional view exemplarily showing the state wherein the DCS semiconductor device shown in FIG. 5 is warped.

FIG. 7 is a sectional view showing a structure of a conventional DCS semiconductor device.

FIG. 8 is a sectional view exemplarily showing the state wherein the DCS semiconductor device shown in FIG. 7 is warped.

FIG. 9 is a sectional view showing a structure of a DCS semiconductor device that is assumed when a top semiconductor chip is made smaller in size than a bottom semiconductor chip.

FIG. 10 is a sectional view exemplarily showing the state wherein the DCS semiconductor device shown in FIG. 9 is warped.

### DETAILED DESCRIPTION

Hereinbelow, preferred embodiments of the present invention will be described in detail with reference to the drawings. In the drawings, the same or corresponding portions are assigned the same reference symbols to thereby incorporate the description thereof.

### FIRST PREFERRED EMBODIMENT

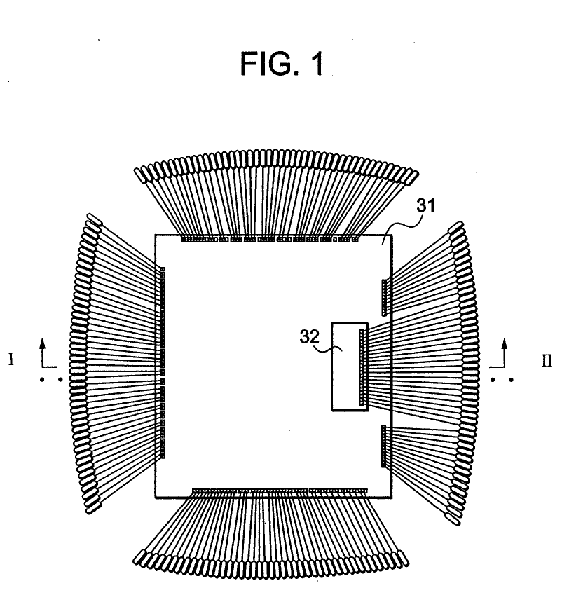

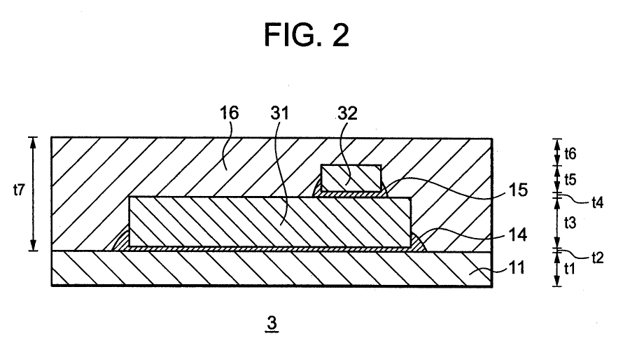

FIG. 1 is a plan view showing an external appearance of a DCS semiconductor device according to the first preferred embodiment of the present invention. FIG. 2 is a sectional view taken along line I-II in FIG. 1.

Referring to FIGS. 1 and 2, this DCS semiconductor device 3 comprises a substrate 11 made of glass epoxy resin or the like, a bottom semiconductor chip 31 including a predetermined electrical circuit (not shown), and a top semiconductor chip 32 including a predetermined electrical circuit (not shown). As a combination of the electrical circuit included in the bottom semiconductor chip 31 and the electrical circuit included in the top semiconductor chip 32, there can be cited, for example, a logic circuit and an analog circuit, a logic circuit and a memory, or the like.

The bottom semiconductor chip 31 is mounted on the substrate 11 using adhesive paste 14. The top semiconductor chip 32 is mounted on the bottom semiconductor chip 31 using adhesive paste 15. The bottom semiconductor chip 31 is electrically connected to the substrate 11 using wire bonding. The top semiconductor chip 32 is electrically connected to the bottom semiconductor chip 31 and the substrate 11 using wire bonding. Because of the limitation on the wire bonding length, the top semiconductor chip 32 is mounted on the bottom semiconductor chip 31 near an end thereof, rather than at the center thereof.

Further, resin 16 is molded on the substrate 11 so as to cover the bottom semiconductor chip 31 and the top semiconductor chip 32.

The DCS semiconductor device 3 differs from the foregoing conventional DCS semiconductor device 1 in that the size of the top semiconductor chip 32 is smaller than that of the bottom semiconductor chip 31, and a thickness t3 of the bottom semiconductor chip 31 is greater than a thickness t5 of the top semiconductor chip 32. The sizes of the bottom semiconductor chip 31 and the top semiconductor chip 32 are not particularly limited, but there can be cited, as an example, a combination of 6mm square (6 mm×6 mm) and 3.5 mm×1.5 mm.

The thickness t3 of the bottom semiconductor chip 31 is maximized while the thickness t5 of the top semiconductor chip 32 is minimized, so as to be received in a thickness t7 of the resin 16. Specifically, assuming that the thickness t7 of the resin 16 is 0.700 mm, inasmuch as it is necessary to ensure 0.040 mm for each thicknesses t2 and t4 of the adhesive pastes 14 and 15 and 0.150 mm for a thickness t6 of an upper space over the top semiconductor chip 32, the thicknesses t3 and t5 of the bottom semiconductor chip 31 and the top semiconductor chip 32 are respectively set to, for example, 0.300 mm and 0.150 mm, or 0.350 mm and 0.100 mm.

A thickness t1 of the substrate 11 is also not particularly limited, but there can be cited, as an example, 0.21 mm, 0.26 mm, 0.32 mm, or the like.

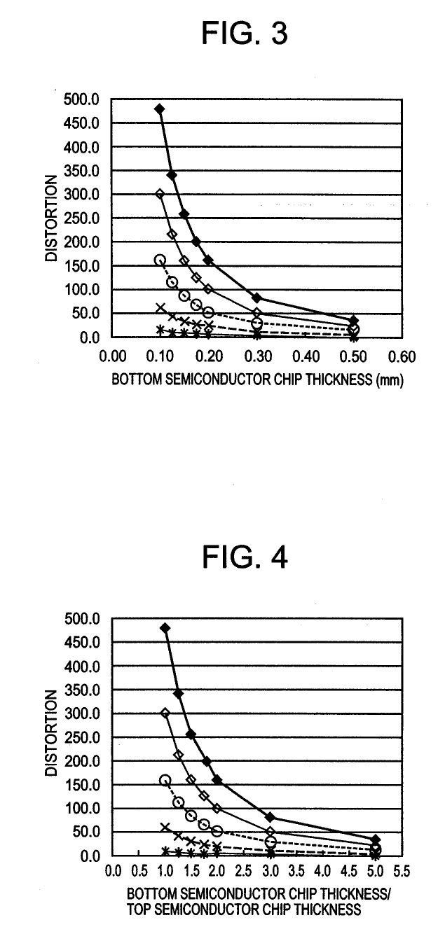

FIG. 3 is a graph showing the relation between the thickness t3 of the bottom semiconductor chip 31 and distortion thereof per size of the bottom semiconductor chip 31. The axis of abscissas represents the thickness t3 (mm) of the bottom semiconductor chip 31, while the axis of ordinates represents the magnitude of distortion (arbitrary unit) at a portion where stresses are concentrated most. With respect to the size of the bottom semiconductor chip 31, represents 10 mm square, 8 mm square, 6 mm square, ×4 mm square, and * 2.5 mm square. By fixing the size of the top semiconductor chip 32 to 2 mm square and the thickness t5 thereof to 0.100 mm, and changing the size of the bottom semiconductor chip 31 from 10.0 mm square to 2.5 mm square, and the thickness t3 thereof from 0.100 mm to 0.500 mm, the relations shown in the graph of FIG. 3 are obtained.

FIG. 4 is a graph wherein the sizes and thicknesses shown in FIG. 3 are converted into the ratios. The axis of abscissas represents the ratio of the thickness t3 of the bottom semiconductor chip 31 relative to the thickness t5 of the top semiconductor chip 32. With respect to the ratio of the size of the bottom semiconductor chip 31 relative to the size of the top semiconductor chip 32, represents 5.0, 4.0, 3.0, ×2.0 and * 1.5. Since the ratio of areas is the square of the ratio of sizes, when the ratio of sizes is converted into the ratio or areas, represents 25.0, 16.0, 9.0, ×4.0, and * 2.25.

As clearly seen from FIGS. 3 and 4, the distortion increases as the ratio of the thickness t3 of the bottom semiconductor chip 31 relative to the thickness t5 of the top semiconductor chip 32 decreases. This relationship becomes more outstanding as the ratio of the size of the bottom semiconductor chip 31 relative to the size of the top semiconductor chip 32 increases. In other words, as the ratio of an area of the top semiconductor chip 32 occupying an area of the bottom semiconductor chip 31 increases, the thickness t3 of the bottom semiconductor chip 31 largely affects the distortion.

Therefore, as the thickness t3 of the bottom semiconductor chip 31 is increased relative to the thickness t5 of the top semiconductor chip 32, the distortion becomes smaller. For example, assuming that the ratio of the size of the bottom semiconductor chip 31 relative to the size of the top semiconductor chip 32 is 5.0 (in case of FIG. 4), the distortion becomes maximum when the thicknesses t3 and t5 of the bottom semiconductor chip 31 and the top semiconductor chip 32 are both 0.100 mm, while, when the thickness t3 of the bottom semiconductor chip 31 is 0.500 mm (5.0 times the thickness t5 of the top semiconductor chip 32), the distortion is reduced to 6.7% of the maximum. Further, for example, assuming that the ratio of the size of the bottom semiconductor chip 31 relative to the size of the top semiconductor chip 32 is 2.0 (in case of × in FIG. 4), when the thickness t3 of the bottom semiconductor chip 31 becomes 0.120 mm or more (no less than 1.2 times the thickness t5 of the top semiconductor chip 32), the distortion becomes smaller than 50.0, i.e. the distortion is reduced to about 80% of the maximum. Accordingly, when the size of the bottom semiconductor chip 31 becomes no less than twice the size of the top semiconductor chip 32, the distortion is further reduced.

As described above, according to the first preferred embodiment, when the top semiconductor chip 32 is smaller than the bottom semiconductor chip 31, the bottom semiconductor chip 31 is made thicker than the top semiconductor chip 32, so that even if the semiconductor device 3 is warped, generated stresses can be reduced. As a result, damage to the bottom semiconductor chip 31 and the substrate 11 can be suppressed to a smaller degree.

### SECOND PREFERRED EMBODIMENT

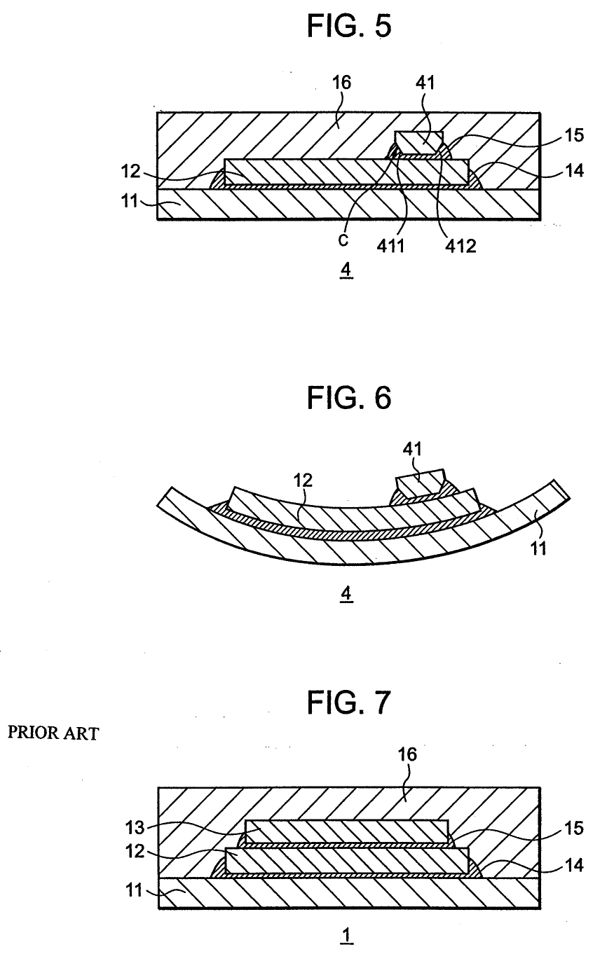

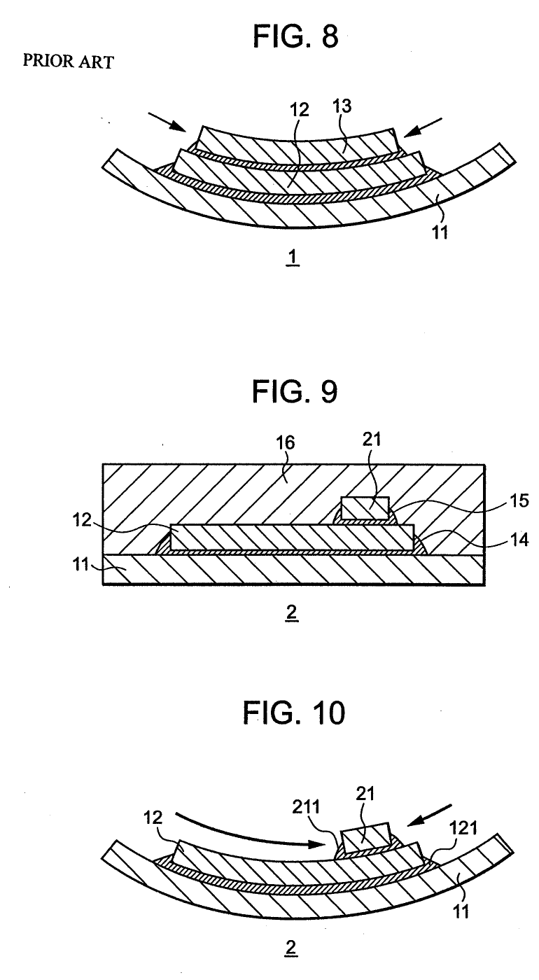

In the foregoing first preferred embodiment, when the size of the top semiconductor chip 32 is smaller than that of the bottom semiconductor chip 31, the thickness of the bottom semiconductor chip 31 is maximized while the thickness of the top semiconductor chip 32 is minimized within the allowable range in terms of the reception of them in the resin 16, for the purpose of reducing the concentrated stresses generated by the warping. On the other hand, in the second preferred embodiment, as shown in FIG. 5, edges 411 and 412 of a lower surface of a top semiconductor chip 41 confronting an upper surface of a bottom semiconductor chip 12 are chamfered.

The top semiconductor chip 41 is generally produced via a dicing process wherein a large plate is cut into strips, and therefore, the foregoing chamfering may be carried out by bevel dicing in the dicing process. The top semiconductor chip 41 has a rectangular parallelepiped shape, and thus has four sides on the lower surface thereof. The chamfering is preferably applied to all the four sides, but may be applied to at least one of the sides where the concentrated stresses are maximized. In case of a semiconductor device 4 shown in FIG. 5, it is sufficient to apply the chamfering to the edge 411 located closer to the center of the bottom semiconductor chip 12. A chamfering width C is not particularly limited. However, when the thickness of the top semiconductor chip 41 is 0.150 mm, it is set to, for example, 0.050 mm to 0.100 mm.

Even if the semiconductor device 4 is warped as shown in FIG. 6, inasmuch as the edges 411 and 412 of the lower surface of the top re chamfered, the stresses are concentrated on the edges 411 and 412 so that no damage is given to the bottom semiconductor chip 12.

In this embodiment, the thickness of the top semiconductor chip 41 is equal to that of the bottom semiconductor chip 12. However, like in the foregoing first preferred embodiment, the thickness of the top semiconductor chip 41 may be set smaller than that of the bottom semiconductor chip 12. That is, the foregoing first preferred embodiment and this second preferred embodiment may be combined together. In this case, the concentrated stresses can be further reduced to thereby further reduce the damage to the bottom semiconductor chip 12 and the substrate 11.

### ANOTHER PREFERRED EMBODIMENT

In the foregoing preferred embodiments, the top semiconductor chip is mounted near the end of the bottom semiconductor chip rather than at the center thereof, which, however, is not necessarily required, i.e. the top semiconductor chip may be mounted at the center of the bottom semiconductor chip. Further, although two semiconductor chips are stacked together in the foregoing preferred embodiments, three or more semiconductor chips may be stacked together.

The description has been given above about the preferred embodiments of the present invention. However, the foregoing preferred embodiments are only the examples for carrying out the present invention. Therefore, the present invention is not limited to the foregoing preferred embodiments, but may be carried out by properly changing the foregoing preferred embodiments without departing from the gist of the present invention.

1. A semiconductor device comprising:
a substrate;
a first semiconductor chip mounted on the substrate; and
a second semiconductor chip mounted on the first semiconductor chip, and being smaller in size and thickness than the first semiconductor chip.

2. The semiconductor device of claim 1, wherein an edge of a lower surface of the second semiconductor chip confronting an upper surface of the first semiconductor chip is chamfered.

3. The semiconductor device of claim 1 wherein the second semiconductor chip is mounted on the first semiconductor chip other than in the center of the first semiconductor chip.

4. The semiconductor device of claim 3 wherein the size of the first semiconductor chip is at least twice the size of the second semiconductor chip.

5. A semiconductor device comprising:
a substrate;
a first semiconductor chip mounted on the substrate; and
a second semiconductor chip, mounted on the first semiconductor chip, being smaller in size than the first semiconductor chip, and having an edge of a lower surface of the second semiconductor chip confronting an upper surface of the first semiconductor chip that is chamfered.

6. The semiconductor device of claim 5 wherein the second semiconductor chip is mounted on the first semiconductor chip closer to an end thereof than at the center thereof.

7. The semiconductor device of claim 6 wherein the size of the first semiconductor chip is at least twice the size of the second semiconductor chip.
